(19) United States
(12) Patent Application Publication
(10) Pub. No.: US 2026/0086165 A1
(43) Pub. Date: Mar. 26, 2026

(54) METHOD AND APPARATUS FOR DIAGNOSING AN ABNORMALITY OF A BATTERY CELL

(71) Applicants: HYUNDAI MOTOR COMPANY, Seoul (KR); KIA CORPORATION, Seoul (KR)

(72) Inventor: Yo Han Baek, Hwaseong-si (KR)

(73) Assignees: HYUNDAI MOTOR COMPANY, Seoul (KR); KIA CORPORATION, Seoul (KR)

(21) Appl. No.: 19/174,690

(22) Filed: Apr. 9, 2025

(30) Foreign Application Priority Data
Sep. 23, 2024 (KR) 10-2024-0128419

(51) Int. Cl. G01R 31/392; G01R 31/367; G01R 31/396

(52) U.S. Cl. CPC G01R 31/392; G01R 31/367; G01R 31/396

(57) ABSTRACT

A method and a computing apparatus diagnose an abnormality of an electric vehicle battery cell. The computing apparatus includes a memory that stores computer-executable instructions. The computing apparatus further includes a processor configured to execute the computer-executable instructions to obtain voltage data for each cell of a plurality of battery cells of a battery of an electric vehicle (EV) during charging or discharging of the battery, generate a time variance table for a reference cell voltage variance for each cell of the plurality of cells by time-series processing the voltage data, and diagnose an abnormal cell of the plurality of battery cells based on the time variance table for the reference cell voltage variance.

### CROSS-REFERENCE TO RELATED APPLICATION

This application claims the benefit of and priority to Korean Patent Application No. 10-2024-0128419, filed in the Korean Intellectual Property Office on Sep. 23, 2024, the entire disclosure of which is incorporated herein by reference.

### TECHNICAL FIELD

The present disclosure relates to a vehicle diagnostic apparatus and method thereof. More particularly, the present disclosure relates to a technology for diagnosing whether a battery cell is abnormal based on voltage and time changes.

### BACKGROUND

As the number of users of electrical vehicles (EVs) increases, the demand for evaluation of the state of health (SOH) of electric vehicle batteries and abnormal state evaluation of an electric vehicle battery has increased in relation to high-voltage battery state certification, EV used car certification, and remanufacturing. The SOH is indicative of how much performance a battery currently has compared to the initial performance of the battery. The SOH is used as an indicator of the remaining battery life and current performance status.

In addition, cell-level abnormal condition diagnosis of a high-voltage battery pack either uninstalled or installed in a vehicle is required in various applications such as remanufacturing, reuse, and recycling of electric vehicle batteries as well as issuance of battery certificates.

Currently, in various applications, current values with relatively high resolution compared to cell voltage values are used as the sensing data values for battery cell abnormality diagnosis. Typically, cell voltage resolution, i.e., accuracy, obtained from a vehicle on-board diagnosis (OBD) or a removable battery system assembly (BSA) is 20 mV level (a typical battery management system (BMS) is 1 mV). However, current data provides a high resolution of 0.1 amperes (A) level (BMS is also 0.1 A).

However, current integration (or current variance)-based abnormality diagnosis algorithms that depend on conventional current sensing values have significantly increased false diagnosis rates if the current sensing values are inaccurate. For example, various disturbances, such as sensing errors due to, e.g., nonlinearity and precision of the current sensor, high-voltage switching noise of a power electronics (PE) system, and the like, cause distortion in the instantaneous current value and increase the amp-hour (Ah) current accumulation error.

Conventional current-based diagnostic schemes may precisely analyze cell behavior. However, current sensing errors occur due to various disturbances described above. Therefore, the reliability of the diagnostic results is low.

Current sensors currently applied to EVs may generally cover a wide charging/discharging current sensing range. However, current sensors have limitations in that the sensing linearity over the entire range is low and the precision is low. In addition, there is a limit to the occurrence frequency of switching pulse current and noise due to various power conversion components, and high-voltage switching noise acts as a disturbance in current sensing.

### SUMMARY

The present disclosure has been made to solve the above-mentioned problems occurring in the prior art while advantages achieved by the prior art are maintained intact. The present disclosure provides a method and apparatus to provide a battery cell abnormality diagnosis scheme that is robust to current sensor performance, PE switching pulse current, and high-voltage noise disturbance.

An aspect of the present disclosure provides a method and an apparatus for diagnosing an abnormality of a battery cell.

Another aspect of the present disclosure provides a method for diagnosing an abnormality of a battery cell and an apparatus capable of diagnosing whether a battery cell is abnormal, i.e., whether there is an abnormality in a battery cell, based on voltage and time variances.

Still another aspect of the present disclosure provides a method for diagnosing an abnormality of a battery cell and an apparatus capable of diagnosing the abnormality of the battery cell by precisely analyzing cell behavior after eliminating the influence of current data by applying a substitute variable to a current sensing value.

The technical problems to be solved by the present disclosure are not limited to the aforementioned problems. Any other technical problems not mentioned herein should be clearly understood from the following description by those of ordinary skill in the art to which the present disclosure pertains.

According to one aspect of the present disclosure, a computing apparatus includes a non-transitory memory configured to store computer-executable instructions. The computing apparatus further includes a processor configured to execute the computer-executable instructions to obtain voltage data for each cell of a plurality of battery cells of a battery of an electric vehicle (EV) during charging or discharging of the battery, generate a time variance table for a reference cell voltage variance for each cell of the plurality of battery cells by time-series processing the voltage data, and diagnose an abnormal cell of the plurality of battery cells based on the time variance table for the reference cell voltage variance.

According to an embodiment, the processor may generate a change trend graph based on the time variance table for the reference cell voltage variance, select an abnormal value detection target inflection point by searching for at least one inflection point on the change trend graph, and diagnose the abnormal cell of the plurality of battery cells based on a cell-specific standard deviation calculated within a range of the selected abnormal value detection target inflection point.

According to an embodiment, the processor may determine a cell-specific sigma level based on the cell-specific standard deviation and determine a risk level for a cell in which the determined cell-specific sigma level exceeds a specified reference sigma.

According to an embodiment, the reference sigma may be 3 sigma and has a higher risk level when the cell-specific sigma level is higher.

According to an embodiment, the time variance table may include a time square variance table for enhancing diagnostic sensitivity.

According to an embodiment, the computing apparatus may be mounted inside diagnostic equipment or the EV.

According to an embodiment, the processor may be further configured to obtain current data for each cell of the plurality of cells and determine a quasi-constant current or constant current section based on the current data after the charging or discharging is completed. The processor may be further configured to process the current data as a constant when calculating a current integration value and not consider the current data in the abnormal value diagnosis.

According to an embodiment, the computing apparatus may further include a network interface that communicates with a server, and the processor may transmit an abnormal value diagnosis result to the server via the network interface.

According to an embodiment, the computing apparatus may further include a user interface input device. The processor may be configured to set information about a voltage variation analysis section input via the user interface input device and information about the reference cell voltage variance. The information about the voltage variation analysis section may include a cell voltage upper limit value and a cell voltage lower limit value.

According to an embodiment, the computing apparatus may be implemented in a battery management system (BMS) of the EV.

According to another aspect of the present disclosure, a method for diagnosing an abnormality of a battery cell in a computing apparatus includes collecting voltage data for each cell of a plurality of battery cells of a battery of an electric vehicle (EV) during charging or discharging of the battery, generating a time variance table for a reference cell voltage variance for each cell of the plurality of battery cells by time-series processing the voltage data, and diagnosing an abnormal cell of the plurality of battery cells based on the time variance table for the reference cell voltage variance.

According to an embodiment, the method may further include generating a change trend graph based on the time variance table for the reference cell voltage variance, selecting an abnormal value detection target inflection point by searching for at least one inflection point on the change trend graph, and diagnosing the abnormal cell based on a cell-specific standard deviation calculated within a range of the selected abnormal value detection target inflection point.

According to an embodiment, the method may further include determining a cell-specific sigma level based on the cell-specific standard deviation and determining a risk level for a cell in which the determined cell-specific sigma level exceeds a specified reference sigma.

According to an embodiment, the reference sigma may be 3 sigma. The reference sigma may have a higher risk level when the cell-specific sigma level is higher.

According to an embodiment, the time variance table may include a time square variance table for enhancing diagnostic sensitivity.

According to an embodiment, the computing apparatus may be implemented in diagnostic equipment or a battery management system (BMS) mounted in the EV.

According to an embodiment, the method may further include obtaining current data for each cell, determining a quasi-constant current or constant current section based on the current data after the charging or discharging is completed, processing the current data as a constant when calculating a current integration value, and not considering the current data in the abnormal value diagnosis.

According to an embodiment, the method may further include transmitting an abnormal value diagnosis result to a server.

According to an embodiment, the method may further include setting information about a voltage variation analysis section input via a user interface input device and information about the reference cell voltage variance before generating the table, wherein the information about the voltage variation analysis section may include a cell voltage upper limit value and a cell voltage lower limit value.

According to an embodiment, the method may further include terminating the charging or discharging based on completion of the data collection.

### BRIEF DESCRIPTION OF THE DRAWINGS

The above and other objects, features, and advantages of the present disclosure should be more clearly understood from the following detailed description taken in conjunction with the accompanying drawings, in which:

FIG. 1 is a diagram illustrating a configuration of an electric vehicle according to an embodiment of the present disclosure;

FIG. 2 is a graph illustrating a problem and error occurrence when a conventional electric vehicle battery cell abnormality diagnosis mechanism and method is used;

FIGS. 3A and 3B show diagrams illustrating a noise separation concept according to an embodiment of the present disclosure;

FIGS. 4-6 show diagrams illustrating a data preprocessing procedure for battery cell diagnosis according to an embodiment of the present disclosure;

FIG. 7 shows diagrams illustrating a method of enhancing abnormality diagnosis sensitivity according to an embodiment of the present disclosure;

FIG. 8 shows diagrams illustrating an example of abnormality diagnosis at the t² inflection point according to an embodiment of the present disclosure;

FIG. 9 is a flowchart illustrating a method of diagnosing an abnormality of an electric vehicle battery cell according to an embodiment of the present disclosure;

FIG. 10 is a flowchart illustrating in more detail the method of diagnosing an abnormality of an electric vehicle battery cell of FIG. 9;

FIG. 11 is a block diagram illustrating the configuration of a battery cell abnormality diagnosis system using diagnostic equipment for an electric vehicle-unmounted battery pack according to an embodiment of the present disclosure;

FIG. 12 is a block diagram illustrating the configuration of a battery cell abnormality diagnosis system using diagnostic equipment for a vehicle-mounted battery pack according to another embodiment of the present disclosure;

FIG. 13 is a block diagram illustrating the configuration of a battery cell abnormality diagnosis system using an in-vehicle controller for a vehicle-mounted battery pack according to still another embodiment of the present disclosure;

FIG. 14 is a block diagram illustrating the configuration of a battery cell abnormality diagnosis system using a controller and a discharge device mounted inside a vehicle for a vehicle-mounted battery pack according to still another embodiment of the present disclosure;

FIG. 15 is a flowchart illustrating an electric vehicle battery cell abnormality diagnosis procedure according to an embodiment of the present disclosure; and FIG. 16 is a block diagram illustrating a computing system according to an embodiment of the present disclosure.

### DETAILED DESCRIPTION

Various embodiments of the present disclosure are described in detail with reference to the accompanying drawings. In adding the reference numerals to the components of each drawing, it should be noted that the identical or equivalent component is specified by the identical numeral even if they are displayed on different drawings. Further, in describing various embodiments of the present disclosure, a detailed description of the related known configurations, features, or functions is omitted where it is determined that a detailed description thereof interferes with the understanding of the embodiments of the present disclosure.

Terms, such as first, second, A, B, (a), (b) or the like may be used to describe components of the present disclosure. The terms are provided only to distinguish the elements from other elements. The essences, sequences, orders, and numbers of the elements are not limited by the terms. In addition, unless defined otherwise, all terms used herein, including technical or scientific terms, have the same meanings as those generally understood by those of ordinary skill in the art to which the present disclosure pertains. The terms defined in the generally used dictionaries should be construed as having the meaning that coincides with the meaning of the context of the related technologies and should not be construed as an ideal or excessively formal meaning unless clearly defined in the specification of the present disclosure.

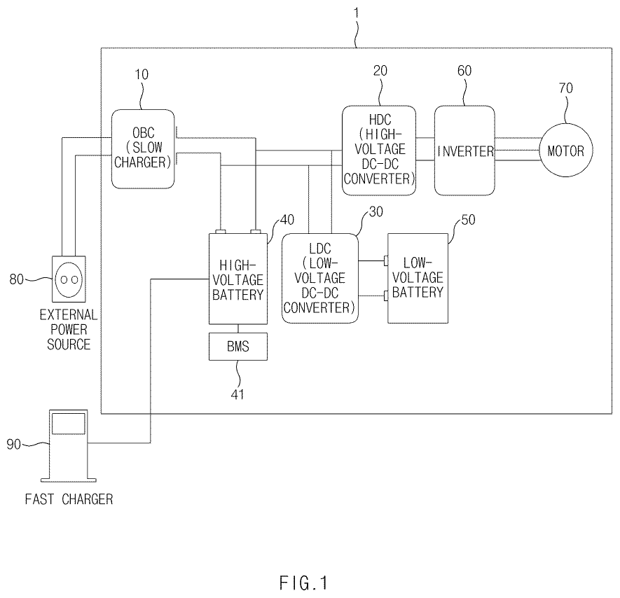

Various embodiments of the present disclosure are described below in detail with reference to FIGS. 1-16. When a component, device, element, or the like of the present disclosure is described as having a purpose or performing an operation, function, or the like, the component, device, or element should be considered herein as being “configured to” meet that purpose or to perform that operation or function. The present disclosure describes various components of a diagnosis apparatus. Each of these components or the like may separately embody or be included with a processor and a memory, such as a non-transitory computer readable media, as part of the component. Further, the phrase “coupled with” is defined to mean directly connected to or indirectly connected through one or more intermediate components.

FIG. 1 is a diagram illustrating a configuration of an electric vehicle according to an embodiment of the present disclosure.

Referring to FIG. 1, an electric vehicle 1 may include an on-board charger (OBC) 10, a high-voltage DC-DC converter (HDC) 20, a low-voltage DC-DC converter (LDC) 30, a high-voltage battery 40, a battery management system (BMS) 41, a low-voltage battery 50, an inverter 60, and a motor 70.

The OBC 10 is a component for slowly charging the high-voltage battery 40 by a converter that receives power from an external AC power source 80 and performs AC-DC conversion.

The HDC 20 is a component for DC-DC converting power from the high-voltage battery 40 and providing it to the inverter 60.

The LDC 30 is a converter system that converts DC power from the high-voltage battery 40 into low-voltage power of 12 V required by most parts of a vehicle, e.g., headlights, wipers, controllers, and the like and provides the low-voltage power to the low-voltage battery 50.

The inverter 60, which is a power conversion device for driving the motor 70, is a component that converts DC into three-phase AC. The inverter 60 may control the speed and direction of the motor 70 and may perform a regenerative braking function.

The high-voltage battery 40 may also be charged by directly receiving power from a fast charger 90 for fast charging.

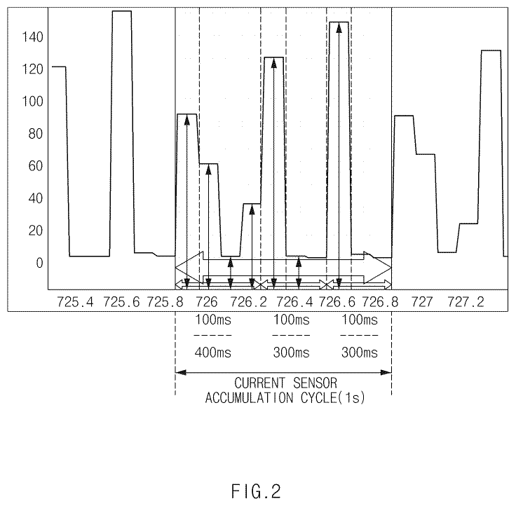

FIG. 2 is a graph illustrating a problem and error occurrence when a conventional electric vehicle battery cell abnormality diagnosis mechanism and method is used.

Because the amount of current changes over a wide range during driving and charging due to the nature of EVs and the current waveform being irregular, i.e., the current slope changes rapidly, current sensors used for diagnosing electric vehicle battery cells must maintain linearity over a wide range and have responsiveness over a variety of frequency ranges, vibration resistance, and environmental temperature resistance. However, it is realistically difficult to find a current sensor that satisfies the required performance while being price competitive.

In particular, in a power conversion system that uses a high-voltage battery as a power source, such as an EV, and in an environment where current distortion increases due to high-frequency switching of a nonlinear load and a pulsed load, current waveform distortion and noise may occur due to the power electronics (PE) system. In this case, the PE system refers to a power conversion system that converts high-voltage battery power via an inverter to drive a motor, thereby moving the vehicle.

Current sensing errors may occur due to power semiconductor switching noise and pulse current of an OBC, an LDC, an inverter, a positive temperature coefficient (PTC), and the like. When sensing errors accumulate, the accuracy and reliability of a battery cell diagnosis may rapidly degrade. In this case, the PTC may refer to a semiconductor material or component having a large positive temperature coefficient, and may refer to a positive temperature coefficient thermistor, commonly known as a PTC thermistor. A PTC thermistor is a type of temperature-sensitive semiconductor resistor whose resistance rapidly increases with increasing temperature if the temperature exceeds a specified threshold (Curie temperature).

A mechanism of current sensing error occurrence in PE systems is described below.

As shown in FIG. 2, due to the combination of power conversion switching of PE and nonlinear current of PTC, the current waveform is generated in a non-repetitive and nonlinear pulse shape with durations (i.e., pulse durations) of several hundred milliseconds. A current sensor measures values in units of time, e.g., one second, and current integration errors increase due to random and nonlinear characteristics. For example, if the pulse is sensed at a time point at which the pulse is large, the pulse may be accumulated as if a large current flowed for 1 second. If the pulse is sensed at a time point at which the pulse is small, the pulse may be accumulated as if a small current flowed for 1 second.

A method for solving the problem of current sensing errors in the PE system described above is described in detail below.

The current accumulation value may be expressed as Equation 1 below.

$${I}_{accumulate} [ Ah ] = I [ A ] \times t [ hour ] \qquad ▯ Equation 1 ▯$$

where I_{accumulate} is the current accumulation value expressed in Ah units, I is the current expressed in A units, t is the time expressed in hour units, I [A] is a factor affected by sensor error and disturbance, and I may be expressed as Equation 2 below.

$$I = {i}_{real} + {i}_{noise} \qquad ▯ Equation 2 ▯$$

According to Equations 1 and 2, the current accumulation value (I_{accumulate}) may be expressed as Equation 3 below.

$${I}_{accumulate} [ Ah ] = ( {i}_{real} + {i}_{noise} ) [ A ] \times t [ hour ] \qquad ▯ Equation 3 ▯$$

where iᵣₑₐₗ is the current not including noise, iₙₒᵢₛₑ is the current including noise, both of which are expressed in A units, and t is the time expressed in hour units. If Equation 3 is expanded, it is as follows.

$${I}_{accumulate} [ Ah ] = {i}_{real} [ A ] \times t [ hour ] + {i}_{noise} [ A ] \times t [ hour ]$$

As shown in Equation 3, as the time term (t) is multiplied by the current including noise (iₙₒᵢₛₑ), the error of the current accumulation value increases.

If a constant current load flows, ‘i’ may be replaced by a constant and Equation 3 may be interpreted as a first-order equation expressed as Equation 4 below.

$${I}_{accumulate} [ Ah ] = I [ A ] \times t [ hour ] \qquad ▯ Equation 4 ▯$$

$$( Replace I with constant ‘ a ’ ) \to Y = a \cdot X$$

In Equation 4, ‘Y’ may be interpreted as a first-order equation proportional to ‘X’ with ‘a’ as a proportional constant. Therefore, ‘Y’ may be interpreted as being only a function of time variance and does not include a current component. In other words, in Equation 4, ‘a’ represents the current value and is the same for all battery cells. Further, ‘X’ represents time and only the X value is different for each battery cell. For example, X_{cell001} and X_{cell002} have different values but they are multiplied by ‘a’ in common. Therefore, no matter what the value of ‘a’ is, the relative magnitudes of X_{cell001} and X_{cell002} are the same. In particular, because ‘a’ is a term that is multiplied equally across all battery cells, ‘a’ only affects the average when calculating the standard deviation and does not affect the relative standard deviation.

A battery cell abnormality diagnosis algorithm according to the present disclosure uses only the standard deviation and relative values when detecting abnormality of cells and ignores the absolute value of the average. As a result, the battery cell abnormality diagnosis algorithm according to the present disclosure is capable of detecting abnormalities for each battery cell by considering only the time variable (t) without considering the constant (constant current value i) when detecting abnormalities, thereby preventing abnormality diagnosis errors due to current accumulation value errors in advance.

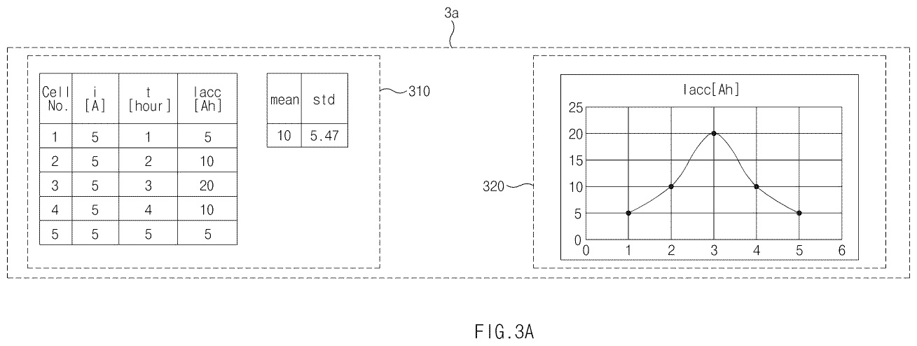

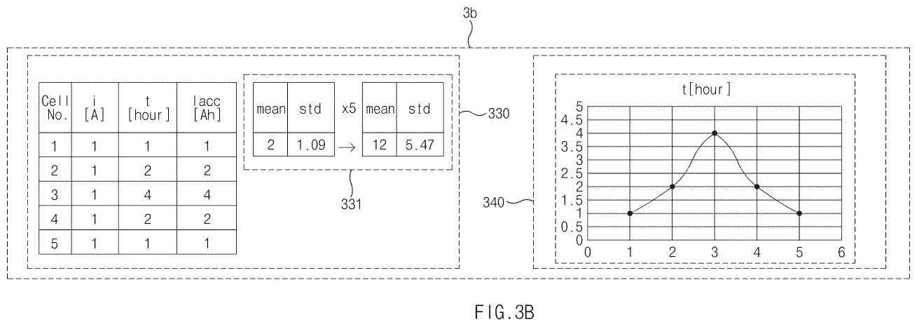

FIGS. 3A and 3B are diagrams illustrating a noise separation concept according to an embodiment of the present disclosure.

In particular, FIGS. 3A and 3B are diagrams for comparing data waveforms when a constant current (CC) is reflected, as shown in FIG. 3A, and when the constant current value is replaced with a constant, as shown in FIG. 3B.

Comparing the data tables of reference numerals 310 and 330 of FIGS. 3A and 3B, respectively, when the standard deviations when 5 A is applied as constant current ‘i’ and when constant current ‘i’, which is a factor causing errors in battery diagnosis, is replaced with a constant value, e.g., ‘1’ are compared, the absolute values are 5.47 and 1.09, respectively, but the relative values are the same. In other words, as indicated by reference numeral 331 in FIG. 3B, it may be understood that the calculated standard deviation value of 1.09 multiplied by the scale of 5, is the same as the standard deviation if the constant current value is applied.

Comparing the waveforms of reference numerals 320 and 340 of FIGS. 3A and 3B, respectively, it may be understood that the waveforms of the two data are the same even though the magnitudes of the constant current values, which are proportional constants, are different.

If the constant current value, which is a factor causing errors in the calculation for battery cell abnormality diagnosis, is replaced by a specific constant value, e.g., 1, and only the time variable t is used, the noise separation method according to the present disclosure may remove the disturbance caused by the current and separate only the unique characteristic values of each cell.

In other words, the noise separation method according to the present disclosure may obtain more accurate battery abnormality diagnosis results by removing noise components except for valid (or highly reliable) values when comparing relative values between different battery cells.

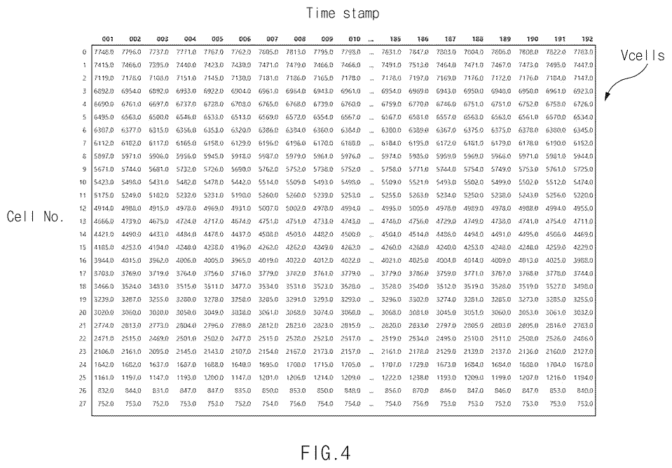

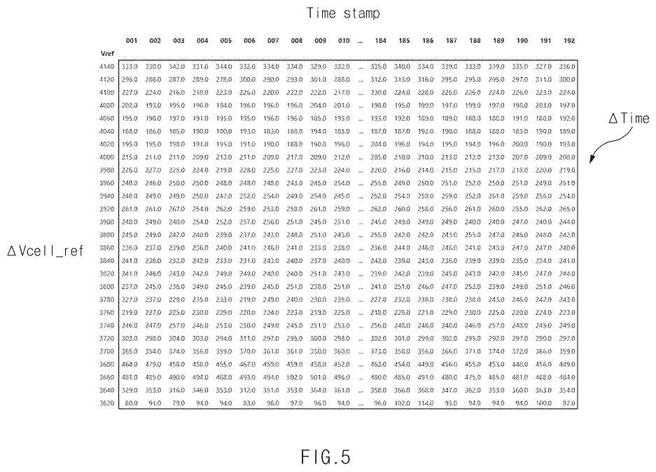

FIGS. 4-6 are diagrams illustrating a data preprocessing procedure for battery cell diagnosis according to an embodiment of the present disclosure.

A conventional preprocessing algorithm generates a current (Ah) table for each cell.

However, the preprocessing algorithm according to the present disclosure generates a time (t) table for each cell. In other words, the preprocessing algorithm according to the present disclosure does not generate a separate current table.

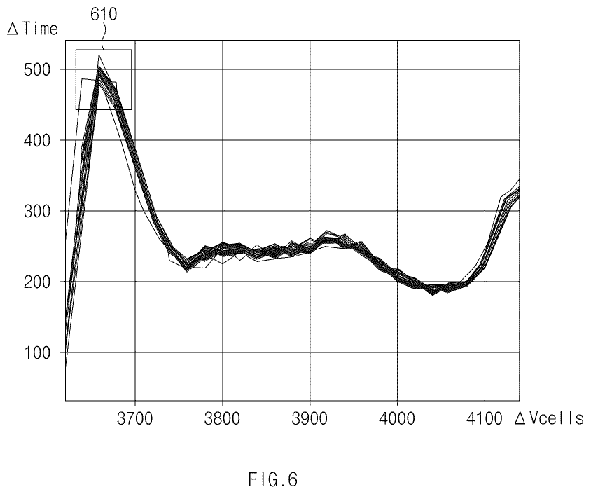

The process of generating a time table is described in detail below.
1) As illustrated in FIG. 4, a voltage and timestamp table for all cells of a battery is generated during constant current discharge or charge.
2) As illustrated in FIG. 5, a time variance (ΔTime) table for voltage change or reference voltage variance (ΔVcell_ref) is generated for each cell.
3) As illustrated in FIG. 6, a change trend graph for each cell is generated based on the time variance table.

Hereinafter, with reference to FIG. 6 described above, the main processing procedure according to the present disclosure is described below in detail. In this case, the main processing procedure refers to the procedure for diagnosing an abnormal state of a battery cell.

Referring to FIG. 6, the diagnostic equipment may search for an inflection point 610 on the change trend graph for each cell and detect the inflection point 610.

The diagnostic equipment may extract the time variance (ΔTime) value for each cell in the detected inflection point 610 region with reference to the time variance (ΔTime) table for the voltage change (ΔVcell) for each cell previously generated.

The diagnostic equipment may calculate the standard deviation for the ΔTime value for each cell corresponding to the inflection point 610 region.

The diagnostic equipment may diagnose a cell with a standard deviation greater than a specified sigma as an erroneous cell or an abnormal cell. In one embodiment, the diagnostic equipment may diagnose a cell with a standard deviation of 3 sigma or more or 4 sigma or more as an abnormal cell. The reference value for determining an abnormal cell may be defined differently depending on the design by a person of ordinary skill in the art.

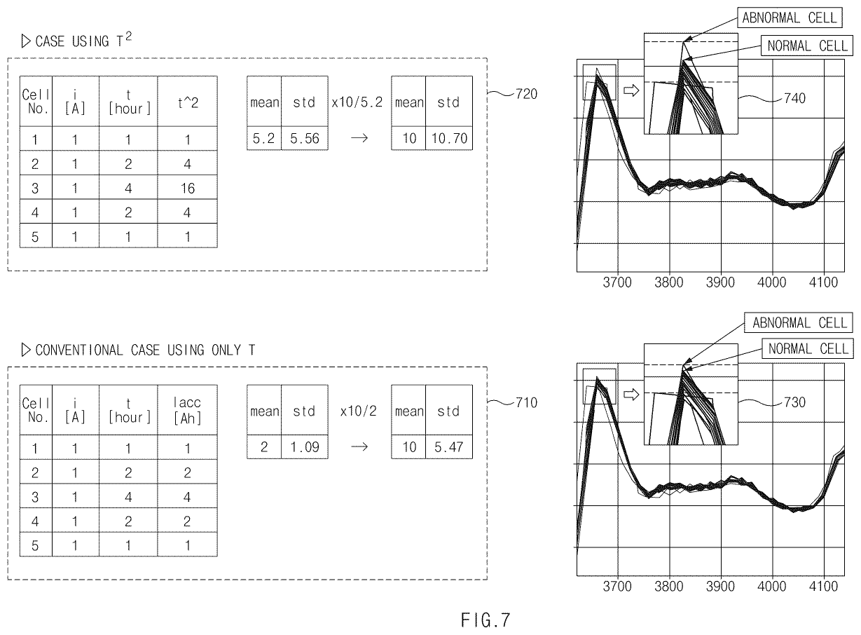

FIG. 7 is a diagram illustrating a method of enhancing abnormality diagnosis sensitivity according to an embodiment of the present disclosure.

In an embodiment, the procedure of enhancing abnormality diagnosis sensitivity may be additionally performed in the above-described preprocessing stage.

As described above, the abnormality diagnosis algorithm according to an embodiment of the present disclosure may reduce the error risk by removing the current component noise, so that the abnormality diagnosis accuracy is improved by maximizing the relative size of data for each cell, i.e., the time variance.

The abnormality diagnosis algorithm according to an embodiment may significantly increase the sensitivity of detecting an abnormal value by generating data in the form of a narrower normal distribution, i.e., by increasing the proportion of averages, by using a second-order time variable (t²) instead of a first-order time variable (t), as indicated by reference numerals 710 and 720 of FIG. 7.

As indicated by reference numerals 730 and 740, if the second-order time variable (t²) is used instead of the first-order time variable (t), the relative standard deviation increases from 5.47 to 10.70, thereby greatly increasing the resolution for the time variance at the inflection point. Thus, the diagnostic equipment may more accurately distinguish between abnormal and normal cells via increased resolution in the inflection point region.

The diagnostic equipment may generate a time variance square table in the preprocessing stage to maximize the relative size of each cell.

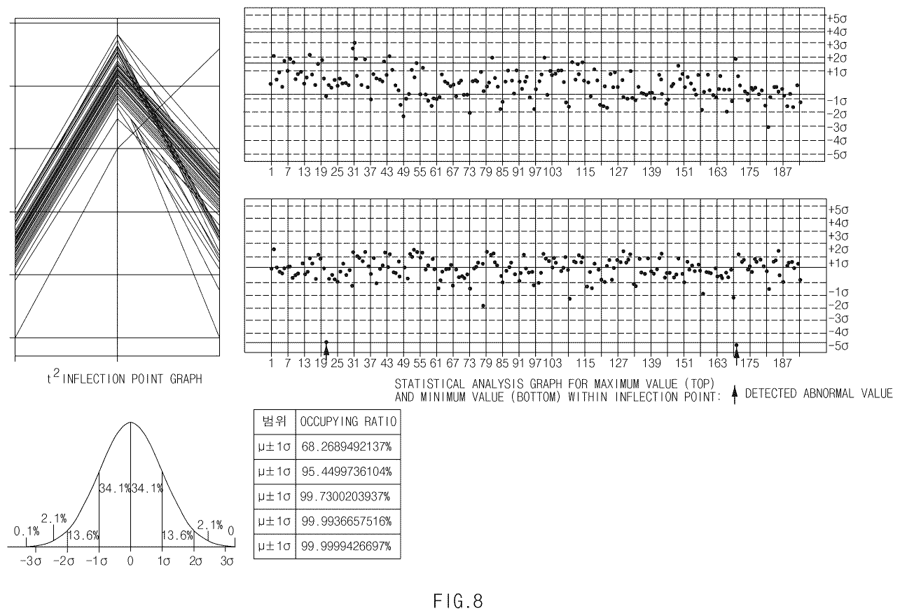

FIG. 8 is a diagram illustrating an example of an abnormality diagnosis at the t² inflection point according to an embodiment of the present disclosure.

Referring to FIG. 8, an outlier that exceeds a certain sigma level may be detected on a statistical graph in the t2 inflection point region. For example, after calculating the standard deviation for each maximum and minimum value of all cells of t², a cell exceeding the range of 1 sigma to 3 sigma (μ±1 to 3σ) may be diagnosed as an abnormal cell.

The risk level may be classified according to the sigma level of the corresponding cell in the t² inflection point region. For example, if the sigma level exceeds ±4 sigma, it may be diagnosed as an abnormal cell, if the sigma level is ±(3˜4) sigma, it may be diagnosed as an abnormal warning cell, and if the sigma level is ±(2˜3) sigma, it may be diagnosed as an abnormal caution cell.

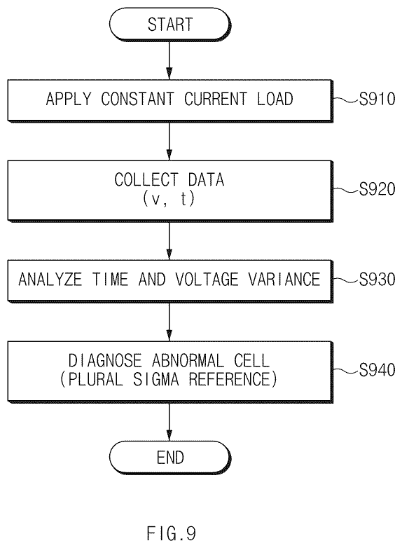

FIG. 9 is a flowchart illustrating a method of diagnosing an abnormality of an electric vehicle battery cell according to an embodiment of the present disclosure.

Hereinafter, the process of FIG. 9 may be performed via a battery cell abnormality diagnosis system. It should be understood that the operations described are being performed by a system or device controlled by a processor included in the battery cell abnormality diagnosis system.

Referring to FIG. 9, in S910, the diagnostic equipment may apply a constant current load to a high voltage battery.

In S920, the diagnostic equipment may collect cell unit data while charging or discharging the high voltage battery. In this case, the collected data may include data on voltage (v) and time (t) of each cell. The diagnostic equipment may generate a table of time variance for voltage change per cell based on the collected data. In an embodiment, the diagnostic equipment may generate a time-variance square table to enhance the abnormal value diagnosis sensitivity according to the presetting of a user.

In S930, the diagnostic equipment may perform time and voltage variance analysis. In an embodiment, the diagnostic equipment may analyze the change trend graph for each cell generated based on the time variance table for voltage changes of each cell. The diagnostic equipment may search for and detect an inflection point on the change trend graph. The diagnostic equipment may calculate the standard deviation for the time variance of each cell within the detected inflection point region.

In S940, the diagnostic equipment may diagnose an abnormal cell based on a result of analyzing the change trend graph analysis. For example, the diagnostic equipment may determine a sigma level based on the calculated standard deviation for each cell and determine a risk level for each cell based on the determined sigma level.

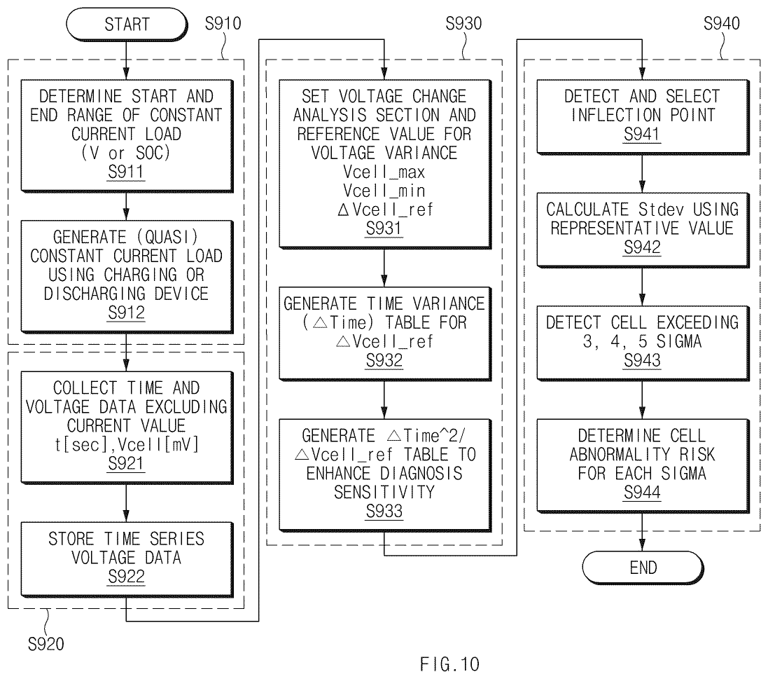

FIG. 10 is a flowchart illustrating in more detail the method of diagnosing an abnormality of an electric vehicle battery cell of FIG. 9.

Referring to FIG. 10, in S911, the diagnostic equipment may determine and set the start and end range of the constant current load. In this case, the start and end time points may be determined based on the battery voltage (V) or state of charging (SOC).

In S912, the diagnostic equipment may generate a (quasi) constant current load by controlling the charging or discharging device.

In S921, the diagnostic equipment may collect time and voltage data excluding current values. For example, the diagnostic equipment may obtain the time and voltage data from the BMS via diagnostic communication.

In S922, the diagnostic equipment may sort the voltage data in time series and then store it in an internal memory. For example, the diagnostic equipment may generate and store a timestamp table for all cell voltages.

In S931, the diagnostic equipment may set a voltage change analysis section and a reference value for a voltage variance. For example, the set reference value may include a cell voltage upper limit Vcell_max, a cell voltage lower limit Vcell_min, and a reference cell voltage variance ΔVcell_ref. As an example, the diagnostic equipment may filter out data that exceeds the cell voltage upper limit Vcell_max or the cell voltage lower limit Vcell_min among the collected voltage data to exclude them from the analysis.

In S932, the diagnostic equipment may generate a time variance (ΔTime) table for a reference cell voltage variance.

In 933, the diagnostic equipment may generate a time square variance (ΔTime\hat{ }2) table for the reference cell voltage variance to enhance the sensitivity of abnormal value diagnosis.

In S941, the diagnostic equipment may analyze the change trend graph generated based on the time square variance (ΔTime\hat{ }2) table for the reference cell voltage variance to detect an inflection point and select an analysis target inflection point. For example, the analysis target inflection point may be selected as the inflection point at which the cell voltage variance is greatest over a unit time.

In S942, the diagnostic equipment may calculate the standard deviation for each cell by using the representative value within the selected inflection point region.

In S943, the diagnostic equipment may determine the sigma level for each cell based on the calculated standard deviation and detect a cell exceeding a specified sigma level.

In S944, the diagnostic equipment may perform a risk determination based on the sigma level of the detected cell.

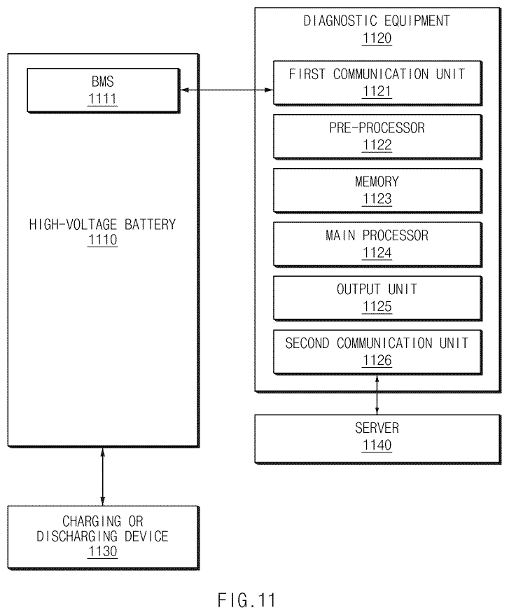

A method of configuring a battery cell abnormality diagnosis system according to various embodiments is described below with reference to FIGS. 11-14.

The battery cell abnormality diagnosis systems described via FIGS. 11-14 may include at least one hardware component for processing data based on one or more computer-executable instructions (commands). At least one hardware component for processing data and for executing the computer-executable instructions may include at least one processor.

FIG. 11 is a block diagram illustrating the configuration of a battery cell abnormality diagnosis system using diagnostic equipment for a battery pack separated from an electric vehicle (i.e., an electric vehicle-unmounted battery pack) according to an embodiment of the present disclosure.

A battery cell abnormality diagnosis system according to an embodiment may include a high-voltage battery 1110, diagnostic equipment 1120, a charging or discharging device 1130, and a server 1140.

As shown in FIG. 11, if a battery pack is separated from a vehicle, the diagnostic equipment 1120 may be connected to a BMS 1111 of the high-voltage battery 1110. The charging or discharging device 1130 may be directly connected to the high-voltage battery 1110.

The diagnostic equipment 1120 may include a first communication unit 1121, a pre-processor 1122, a memory 1123, a main processor 1124, an output unit 1125, and a second communication unit 1126. In this case, the diagnostic equipment 1120 may be implemented in the form of a PC equipped with a specified diagnostic program or a global diagnostic system (GDS) equipped with a standard diagnostic program, but the embodiment is not limited thereto.

The first communication unit 1121 may be connected to the BMS 1111 of the high-voltage battery 1110 to perform diagnostic communication. For example, the first communication unit 1121 may receive all cell voltage measurement data from the BMS 1111 and provide it to the pre-processor 1122. In this case, all cell voltage measurement data may be received at preset cycles.

The pre-processor 1122 may time-series process the voltage measurement data collected from all cells to generate a voltage timestamp table for all cells. Next, the pre-processor 1122 may generate a time variance table for a voltage variance of each cell based on the voltage timestamp table for all cells. In addition, the pre-processor 1122 may generate a time variance square table based on the time variance table for voltage changes of each cell to enhance diagnosis sensitivity according to the pre-menu settings.

The pre-processor 1122 may generate a change trend graph based on the time variance table for voltage changes of each cell and/or the time variance square table.

The pre-processor 1122 may store not only all cell voltage measurement data, which is collected raw data, but also the generated table and graph in the memory 1123.

The main processor 1124 may analyze the graph stored in the memory 1123 to detect inflection points and select inflection points from among the detected inflection points to perform an abnormality diagnosis.

The main processor 1124 may calculate the standard deviation for each cell within the selected inflection point range and determine the sigma level for each cell based on the calculated standard deviation.

The main processor 1124 may identify cells that exceed a specified standard sigma based on the sigma level determined for each cell. In one embodiment, the reference sigma may be set to 3 sigma. A lower or higher sigma may be set as the reference sigma depending on the design by a person of ordinary skill in the art.

The main processor 1124 may determine a cell abnormality risk based on the identified sigma level for each cell exceeding the reference sigma.

The output unit 1125 may visualize the processing result of the main processor 1124 and output it onto a display screen.

The second communication unit 1126 may transmit the processing result of the main processor 1124, i.e., the battery cell abnormality diagnosis result, to the server 1140. In one embodiment, the second communication unit 1126 may access the server 1140 connected to the Internet or a private network. In an embodiment, the second communication unit 1126 may transmit information about tables and graphs generated by the pre-processor 1122 as well as the abnormality diagnosis results by the main processor 1124 to the server 1140.

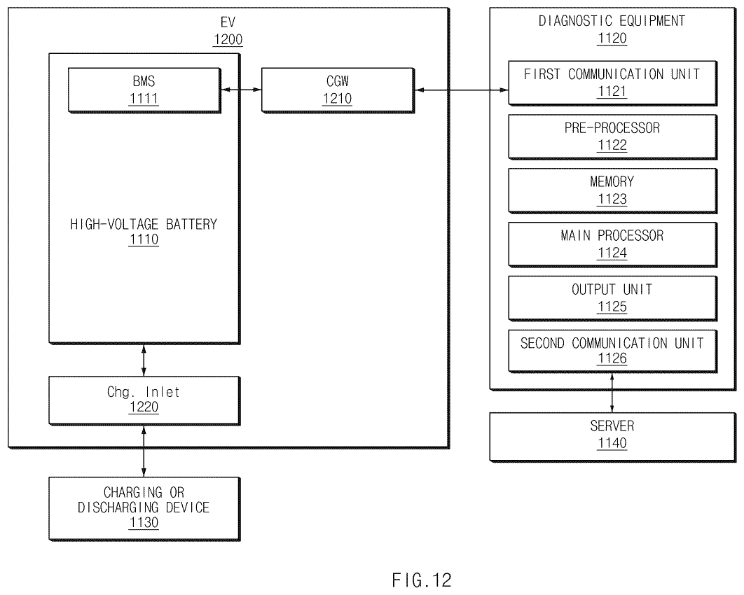

FIG. 12 is a block diagram illustrating a configuration of a battery cell abnormality diagnosis system using diagnostic equipment for a vehicle-mounted battery pack according to another embodiment of the present disclosure.

Referring to FIG. 12, when diagnosing a battery pack mounted on a vehicle, the first communication unit 1121 of the diagnostic equipment 1120 may be connected to the BMS 1111 via a charging gateway (CGW) 1210 mounted on an EV 1200. The charging or discharging device 1130 may charge the high-voltage battery 1110 or charge energy discharged from the high-voltage battery 1110 via a charging inlet 1220 equipped on the EV 1200.

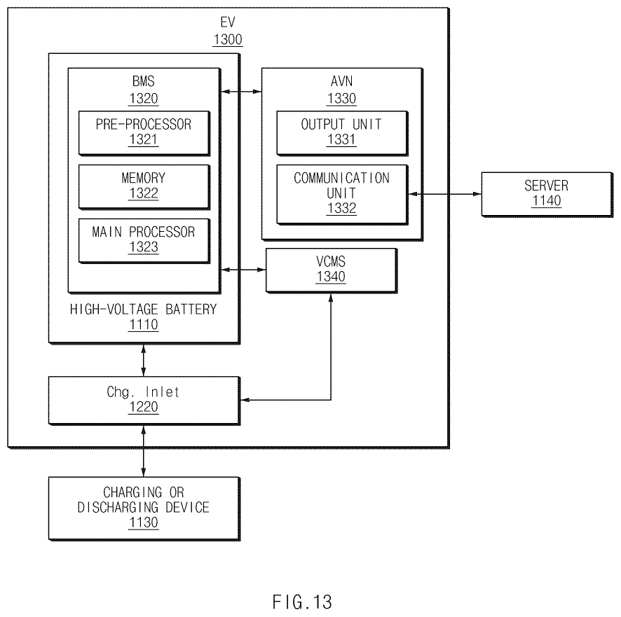

FIG. 13 is a block diagram illustrating a configuration of a battery cell abnormality diagnosis system using an in-vehicle controller for a vehicle-mounted battery pack according to still another embodiment of the present disclosure.

Referring to FIG. 13, the battery cell abnormality diagnosis system may include an EV 1300, the charging and discharging device 1130, and the server 1140. The functions of the diagnostic equipment 1120 of the above-described FIGS. 11 and 12 may be distributed and installed in in-vehicle controllers and devices such as an internal BMS 1320, an audio video navigation (AVN) 1330, and the like in the EV 1300.

The BMS 1320 according to an embodiment may include a preprocessor 1321, storage (e.g., memory) 1322, and a main processor 1323. The functions and operations of the preprocessor 1321, the storage 1322, and the main processor 1323 are identical or similar to those of the pre-processor 1122, the storage 1123, and the main processor 1124 of the diagnostic equipment 1120 in FIGS. 11 and 12 described above, and therefore, the details are the same as those in the description of FIGS. 11 and 12 described above.

The charging or discharging device 1130 according to an embodiment may be implemented to charge the high-voltage battery 1110 or charge energy discharged by the high-voltage battery 1110 via the charging inlet 1220 provided in an EV 1300.

An AVN 1330 may be implemented to be connected to a BMS 1320 via in-vehicle communication such as controller area network (CAN) communication to exchange signals and information.

The cell unit abnormality diagnosis results processed by the main processor 1323 of the BMS 1320 may be visualized by the AVN 1330 and displayed via an output unit 1331.

In addition, a communication unit 1332 equipped in the AVN 1330 may be connected to the external server 1140 and may transmit the cell unit abnormality diagnosis results to the server 1140. The communication unit 1332 may also transmit to the server 1140, information about tables and graphs maintained in the storage 1322 of the BMS 1320 corresponding to the abnormality diagnosis results.

The EV 1300 according to an embodiment may include a vehicle charging management system (VCMS) 1340. The VCMS 1340 is an electric vehicle charging controller that controls and manages the overall charging system of the EV 1300. If power is supplied from outside of the EV 1300 or is provided to the outside, the VCMS 1340 may communicate with the charging or discharging device 1130 via the charging inlet 1220, thereby controlling charging/discharging. The VCMS 1340 may include a charge management system (CMS) that controls slow and rapid charging and a powerline communication module (PCM) that controls rapid charging. The VCMS 1340 may cooperatively control related controllers in the vehicle via CMS and PCM, perform two-way communication with an external charger or discharger, and control charging of the high-voltage battery 1110 or discharging of power charged in the high-voltage battery 1110.

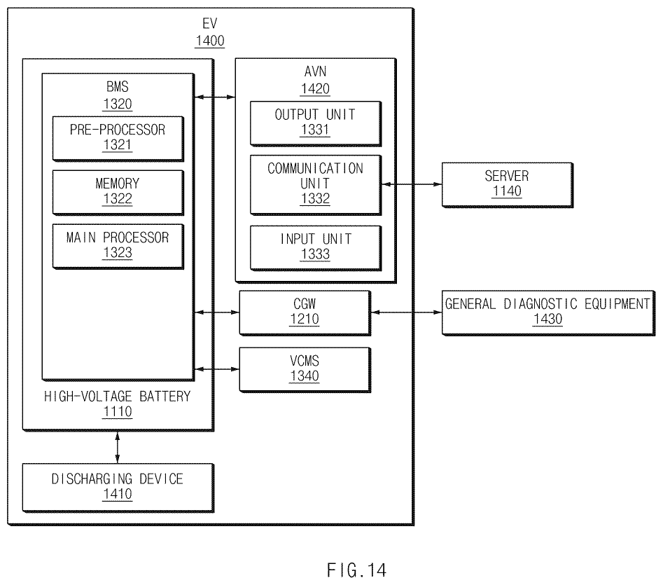

FIG. 14 is a block diagram illustrating the configuration of a battery cell abnormality diagnosis system using a controller and a discharge device mounted inside a vehicle for a vehicle-mounted battery pack according to still another embodiment of the present disclosure.

Referring to FIG. 14, a discharge device 1410 may be provided inside an EV 1400 and an AVN 1420 may further include an input unit 1333 compared to the AVN 1330 of FIG. 13. A user may generate a discharge command via the input unit 1333. For example, the discharge command may be transmitted to the BMS 1320 via in-vehicle communication. In this case, the BMS 1320 may control the energy stored in the high-voltage battery 1110 to be charged to the discharge device 1410 according to the discharge command. In another embodiment, the discharge command may be transmitted to the VCMS 1340 via in-vehicle communication. In this case, the VCMS 1340 may control the energy stored in the high-voltage battery 1110 to be charged to the discharge device 1410 according to the discharge command.

In another embodiment, the discharge command may be generated from a general diagnostic equipment 1430. In this case, the discharge command generated by the general diagnostic equipment 1430 may be transmitted to the BMS 1320 or VCMS 1340 via the CGW 1210. The general diagnostic equipment 1430 according to an embodiment may not be equipped with the battery cell abnormality diagnostic function of the diagnostic equipment 1120 of FIGS. 11 and 12 described above.

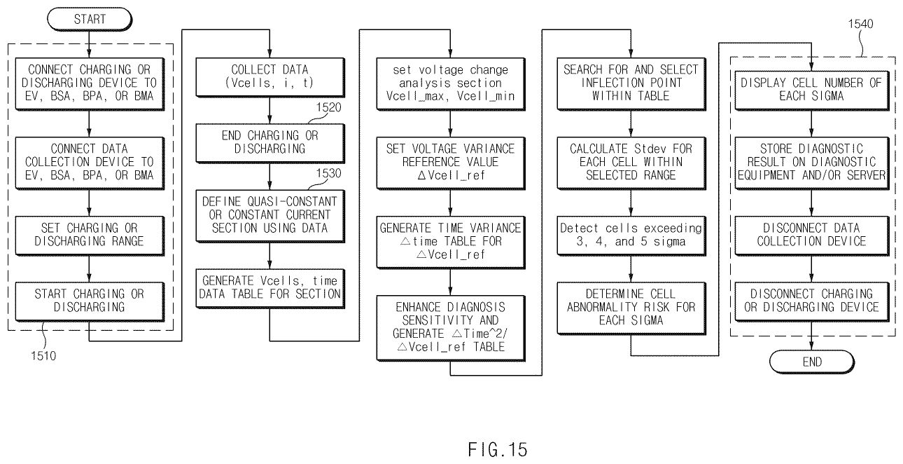

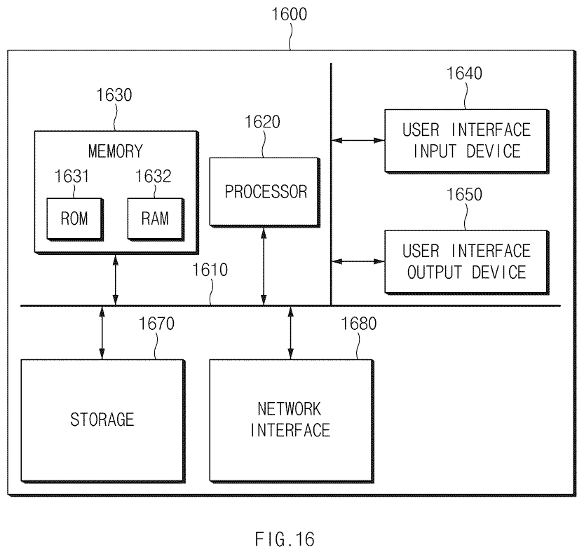

FIG. 15 is a flowchart illustrating an electric vehicle battery cell abnormality diagnosis procedure according to an embodiment of the present disclosure.

Referring to reference numeral 1510 of FIG. 15, according to the embodiments of FIGS. 11-14 described above, the charging and discharging device may be connected to an EV, a battery system assembly (BSA), a battery pack assembly (BPA), or a battery module assembly (BMA), and a device for collecting data may be connected to the connected EV, BSA, BPA, or BMA. In this case, the data collection device may be an external diagnostic equipment, a BSA, a BPA, or a BMS, but the embodiment is not limited thereto. If the connection between the charging or discharging device and the data collection device are completed, the charging and discharging ranges may be set. In this case, the charging and discharging range may be set via external diagnostic equipment or an AVN in the EV, but the embodiment is not limited thereto.

The BMA may be the minimum unit cell assembly that constitutes a battery system, the BPA may be a product that is assembled in a structure in which a specified number of BMAs are assembled to be installed in a vehicle. The BSA may be a final product that is obtained by assembling electrical components to maintain and manage the performance of the BPA.

If the setting of the charging and discharging range is completed, charging or discharging may be controlled to be initiated via selecting a specified menu of external diagnostic equipment or the AVN.

If data collection is completed, charging or discharging may be controlled to stop in S1520. In S1530, the diagnostic equipment or BMS may use current (i) data to determine (or define) a quasi-constant current or constant current section.

Referring to reference numeral 1540, if the cell unit abnormality analysis is completed, the cell number for each sigma is displayed, and the abnormality analysis results may be transmitted to and stored in the diagnostic equipment and/or server. Then, the data collection device and the charging or discharging device connected to the EV, BSA, BPA or BMA may be disconnected.

The remaining operations of FIG. 15 are the same as those described in the description of FIGS. 9 and 10 described above.

FIG. 16 is a block diagram illustrating a computing system according to an embodiment of the present disclosure.

Referring to FIG. 16, a computing system 1600 may include at least one processor 1620, a non-transitory memory 1630, a user interface input device 1640, a user interface output device 1650, storage 1670, and a network interface 1680 which are connected via a bus 1610.

The network interface 1680 according to an embodiment may perform diagnostic communication, in-vehicle communication and/or communication with an external server. The network interface 1680 may include a communication module (or communication modem) for at least one of wired communication with the EV vehicle via a diagnostic cable, in-vehicle communication via an in-vehicle communication network such as CAN communication, and wireless communication via a mobile communication network.

The processor 1620 may be a central processing unit (CPU) or a semiconductor device that processes computer-executable instructions stored in the memory 1630 and/or the storage 1670. The memory 1630 and the storage 1670 may include various volatile or nonvolatile storage media. For example, the memory 1630 may include a read only memory (ROM) 1631 and a random access memory (RAM) 1632.

Accordingly, the processes of the method or algorithm described in relation to the embodiments of the present disclosure may be implemented directly by hardware executed by the processor 1620 or a software module, or a combination thereof. The software module may reside in a storage medium (that is, the memory 1630 and/or the storage 1670), such as a RAM, a flash memory, a ROM, an EPROM, an EEPROM, a register, a hard disk, a detachable disk, or a CD-ROM.

The storage medium is coupled to the processor 1620. The processor 1620 may read information from the storage medium and may write information in the storage medium. In another method, the storage medium may be integrated with the processor 1620. The processor and the storage medium may reside in an application specific integrated circuit (ASIC). The ASIC may reside in a user terminal. In another method, the processor and the storage medium may reside in the user terminal as an individual component.

In an embodiment, the computing system 1600 may be implemented to perform at least one of the functions and methods disclosed in FIGS. 1-15 described above and be applied to at least one of the EV and diagnostic equipment described above.

The present technology provides a method and apparatus for diagnosing an abnormality of a battery cell.

In addition, the present technology provides a method and apparatus for diagnosing an abnormality of a battery cell capable of diagnosing whether a battery cell is abnormal based on voltage and time variances.

In addition, the present technology provides a method and apparatus for diagnosing an abnormality of a battery cell capable of diagnosing the abnormality of the battery cell by precisely analyzing cell behavior after eliminating the influence of current data by applying a substitute variable to a current sensing value.

In addition, the present technology provides a method and apparatus of diagnosing an abnormality of a battery cell that are robust to be able to handle various disturbances such as current sensor performance, PE switching pulse current, and high voltage noise.

In addition, the present technology may improve the diagnostic accuracy of battery cells in various applications that have low voltage resolution and high dependence on current sensing data.

In addition, various effects that are directly or indirectly understood via the present disclosure may be provided.

Although various embodiments of the present disclosure have been described for illustrative purposes, those of ordinary skill in the art should appreciate that various modifications, additions and substitutions are possible, without departing from the scope and spirit of the disclosure.

Therefore, various embodiments disclosed in the present disclosure are provided for the sake of descriptions and should not limit the technical concepts of the present disclosure. It should be understood that such embodiments are not intended to limit the scope of the technical concepts of the present disclosure. The protection scope of the present disclosure should be understood by the claims below. All technical concepts within an equivalent scope should be interpreted to be within the technical scope of the present disclosure.

What is claimed is:

1. A computing apparatus comprising:
a non-transitory memory configured to store computer-executable instructions; and
a processor configured to execute the computer-executable instructions to
obtain voltage data for each cell of a plurality of battery cells of a battery of an electric vehicle (EV) during charging or discharging of the battery,
generate a time variance table for a reference cell voltage variance for each cell by time-series processing of the voltage data, and
diagnose an abnormal cell of the plurality of battery cells based on the time variance table for the reference cell voltage variance.

2. The computing apparatus of claim 1, wherein the processor is further configured to
generate a change trend graph based on the time variance table for the reference cell voltage variance,
select an abnormal value detection target inflection point by searching for at least one inflection point on the change trend graph, and
diagnose the abnormal cell of the plurality of battery cells based on a cell-specific standard deviation calculated within a range of the selected abnormal value detection target inflection point.

3. The computing apparatus of claim 2, wherein the processor is further configured to determine a cell-specific sigma level based on the cell-specific standard deviation, and determine a risk level for a cell in which the determined cell-specific sigma level exceeds a specified reference sigma.

4. The computing apparatus of claim 3, wherein the reference sigma is 3 sigma and has a higher risk level when the cell-specific sigma level is higher.

5. The computing apparatus of claim 1, wherein the time variance table includes a time square variance table for enhancing diagnostic sensitivity.

6. The computing apparatus of claim 1, wherein the computing apparatus is mounted inside diagnostic equipment or the EV.

7. The computing apparatus of claim 1, wherein the processor is further configured to:
obtain current data for each cell of the plurality of battery cells;
determine a quasi-constant current or constant current section based on the current data after the charging or discharging is completed;
process the current data as a constant when calculating a current integration value; and
not consider the current data in an abnormal value diagnosis.

8. The computing apparatus of claim 1, further comprising:
a network interface coupled with the processor and configured to communicate with a server,
wherein the processor is configured to transmit an abnormal value diagnosis result to the server via the network interface.

9. The computing apparatus of claim 1, further comprising:
a user interface input device coupled with the processor,
wherein the processor is configured to set information about a voltage variation analysis section input via the user interface input device and information about the reference cell voltage variance, and
wherein the information about the voltage variation analysis section includes a cell voltage upper limit value and a cell voltage lower limit value.

10. The computing apparatus of claim 1, wherein the computing apparatus is implemented in a battery management system (BMS) of the EV.

11. A method for diagnosing an abnormality of a battery cell in a computing apparatus, the method comprising:
collecting voltage data for all battery cells of a battery of an electric vehicle (EV) during charging or discharging of the battery;
generating a time variance table for a reference cell voltage variance for each cell of the battery cells by time-series processing the voltage data; and
diagnosing an abnormal cell of the battery cells based on the time variance table for the reference cell voltage variance.

12. The method of claim 11, further comprising:
generating a change trend graph based on the time variance table for the reference cell voltage variance;
selecting an abnormal value detection target inflection point by searching for at least one inflection point on the change trend graph; and
diagnosing the abnormal cell of the battery cells based on a cell-specific standard deviation calculated within a range of the selected abnormal value detection target inflection point.

13. The method of claim 12, further comprising:
determining a cell-specific sigma level based on the cell-specific standard deviation; and
determining a risk level for a cell in which the determined cell-specific sigma level exceeds a specified reference sigma.

14. The method of claim 13,
wherein the reference sigma is 3 sigma, and
wherein the reference sigma has a higher risk level when the cell-specific sigma level is higher.

15. The method of claim 11, wherein the time variance table includes a time square variance table for enhancing diagnostic sensitivity.

16. The method of claim 11, wherein the computing apparatus is implemented in diagnostic equipment or a battery management system (BMS) mounted in the EV.

17. The method of claim 11, further comprising:
obtaining current data for each cell;
determining a quasi-constant current or constant current section based on the current data after the charging or discharging is completed;
processing the current data as a constant when calculating a current integration value; and
not considering the current data in an abnormal value diagnosis.

18. The method of claim 11, further comprising:
transmitting an abnormal value diagnosis result to a server.

19. The method of claim 11, further comprising:
setting information about a voltage variation analysis section input via a user interface input device and information about the reference cell voltage variance before generating the table,
wherein the information about the voltage variation analysis section includes a cell voltage upper limit value and a cell voltage lower limit value.

20. The method of claim 11, further comprising:
terminating the charging or discharging based on completion of the data collection.
